(19) United States
(12) Patent Application Publication
(10) Pub. No.: US 2014/0182650 A1
(43) Pub. Date: Jul. 3, 2014

(54) MODULE INTEGRATED CIRCUIT

(71) Applicant: Darren Lochun, Mountain View, CA (US)

(72) Inventor: Darren Lochun, Mountain View, CA (US)

(73) Assignee: Nanosolar, Inc., San Jose, CA (US)

(21) Appl. No.: 13/797,234

(22) Filed: Mar. 12, 2013

Related U.S. Application Data
(60) Provisional application No. 61/746,755, filed on Dec. 28, 2012.

(51) Int. Cl. H01L 31/05

(52) U.S. Cl. CPC H01L 31/0504
USPC 136/244; 136/252; 136/258; 136/261; 136/260; 136/264; 136/265

(57) ABSTRACT

The disclosure relates to apparatus and methods of photovoltaic or solar module design and fabrication. A photovoltaic (PV) module includes one or more photovoltaic cells mounted to a support, a first terminal connected to at least one of the one or more PV cells, a second terminal connected to at least one of the one or more PV cells, and a bypass line mounted to the support for bypassing the one or more PV cells. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

### CLAIM PRIORITY

This application claims the priority benefit of commonly owned, co-pending U.S. Provisional Patent Application No. 61/746,755, to Darren Lochun, filed Dec. 28, 2012, and entitled “MODULE INTEGRATED CIRCUIT” the entire disclosures of which are incorporated herein by reference.

### FIELD OF THE DISCLOSURE

This invention relates generally to solar power systems. More particularly, it relates to apparatus and methods of photovoltaic or solar module design and fabrication.

### BACKGROUND OF THE INVENTION

Solar cells or photovoltaic (PV) cells are devices that convert sunlight into direct current (DC) power. Multiple PV cells are usually electrically connected in series as a solar cell string to form a PV module. A plurality of PV modules are wired together in series and/or parallel to form arrays and then coupled to an inverter, which converts collected power at the desired voltage or alternate current (AC).

Typically, the positive and negative outputs of each PV modules are connected to a combiner box which combines multiple DC inputs from the modules and forms one DC output to the inverter. It is required to run a separate cable during module installation from the end of the solar cell string to the combiner box. Since a PV system may involve a large number of PV modules connected together, such wiring connections to the combiner box results in longer installation process and an increased cost. As such, it is desirable to simplify the wiring connection in a PV system and the installation process.

It is within this context that aspects of the present disclosure arise.

### BRIEF DESCRIPTION OF THE DRAWINGS

FIG. 1 is a circuit diagram of an illustrative PV module of the present disclosure;

FIG. 2A is a circuit diagram of an illustrative PV module of the present disclosure;

FIG. 2B is a cross-sectional diagram illustrating a portion of a PV module of the present disclosure;

FIG. 2C is a cross-sectional diagram illustrating an example of a PV cell that may be used in conjunction with aspects of the present disclosure;

FIG. 3 is a schematic view of an illustrative connector used with a PV module in accordance with the present disclosure;

FIG. 4 is a perspective view of an illustrative PV module assembly of the present disclosure; and

FIG. 5 is an enlarged perspective view depicting portions of an illustrative PV module of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the aspects of the present disclosure described below are set forth without any loss of generality to, and without imposing limitations upon, the claims that follow this description.

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and thus, the description includes both structures wherein a device possesses the anti-reflective film feature and structures wherein the anti-reflective film feature is not present.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc.

According to the aspects of the present disclosure, a photovoltaic (PV) module includes one or more photovoltaic cells mounted to a support, a first terminal connected to at least one of the one or more PV cells, a second terminal connected to at least one of the one or more PV cells, and a bypass line mounted to the support for bypassing the one or more PV cells.

According to the aspects of the present disclosure, a photovoltaic (PV) module assembly comprises a first PV module including a first set of one or more PV cells mounted to a first support, a first terminal connected to at least one of the one or more PV cells in the first PV module, a second terminal connected to at least one of the one or more PV cells in the first PV module, and a first bypass line mounted to the first support bypassing the one or more PV cells in the first PV module, and a second PV module connected in series with the first PV module, the second PV module including a second set of one or more PV cells mounted to a second support, a third terminal connected to at least one of the one or more PV cells in the second PV module, a fourth terminal connected to at least one of the one or more PV cells in the second PV module, and a second bypass line mounted to the second support bypassing the one or more PV cells in the second PV module. The second terminal of the first PV module is electrically connected to the third terminal of the second PV module. The first bypass line is electrically connected to the second bypass line.

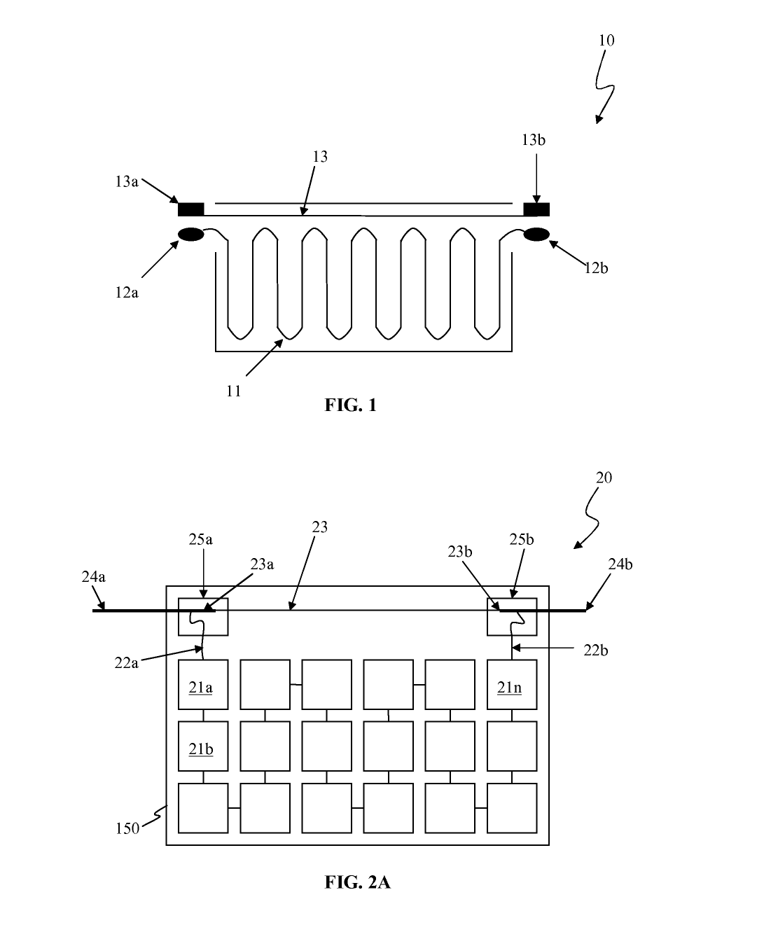

A PV assembly may have a plurality of PV modules connected in series. FIG. 1 is a circuit diagram of one illustrative PV module in a PV assembly of the present disclosure. As known in the art, a PV module 10 may include a number of PV cells (not shown) connected in series to form a PV cell string 11. A PV cell may be made of monocrystalline silicon, polycrystalline silicon, amorphous silicon, cadmium telluride, cooper indium selenide/sulfide or any other suitable materials. At the front end of the PV cell string 11, a negative terminal 12a receives an input from an upstream PV module. The back end of the cell string 11 has a positive terminal 12b for output to a downstream PV module that is connected in series. In the PV module 10, a bypass line 13 with terminals 13a and 13b is provided to transmit the output from the last connected PV module in the PV module assembly back to the first PV module in the assembly. The bypass line 13 may be laminated and integrated within the module 10.

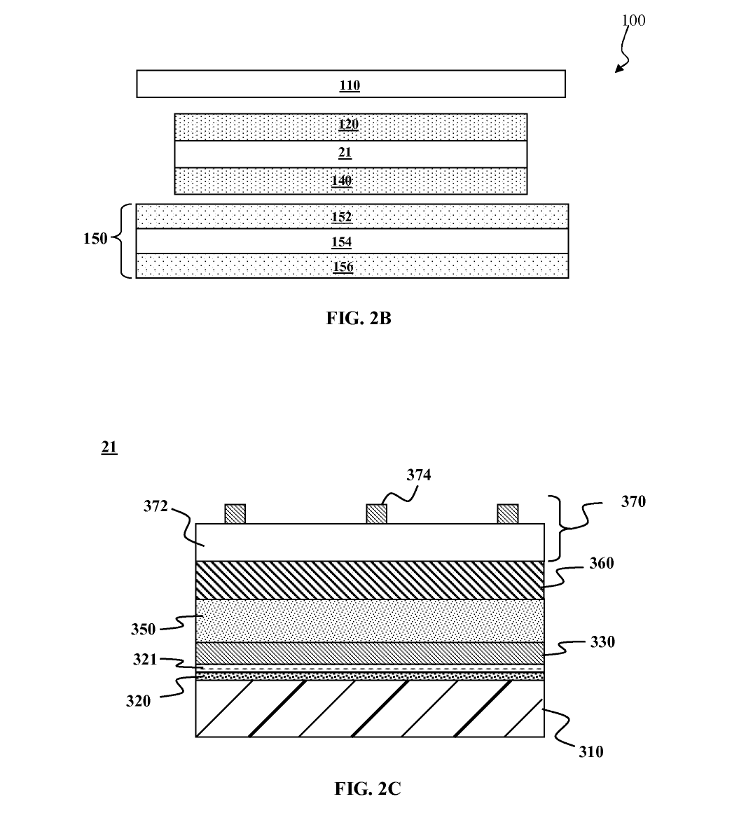

FIG. 2A is a circuit diagram of an illustrative PV module of the present disclosure. A PV module 20 includes a plurality of PV cells (21a, 21b . . . 21n) which are connected in series. The cells are mounted to a support 150. A corner box 25a is, in one example, located at one corner in the module 20 while a corner box 25b is at another corner. It is understood that the corner boxes 25a and 25b may be placed in another area in the module as deemed appropriate by those skilled in the art. The corner boxes 25a and 25b may provide housing for wiring connections. By way of example, and not by way of limitation, a bipolar cable 24a may provide an input from the output of an upstream PV module and enters into the corner box 25a where it is bifurcated into two cables 22a and 23a. The cable 22a is electrically connected to the first cell 21 a in the series connection of the PV cells in the module 20. The cable 23a is electrically connected to cable 23b in the corner box 25b through a bypass cable 23. In addition, the output of the last cell 21b in the series is coupled to a cable 22b. In the corner box 25b, the cable 23b is combined with cable 22b to form a bipolar cable 24b. The bipolar cable 24 may be in turn connected to a bipolar cable of the next module (not shown) in the series.

FIG. 2B shows a non-to-scale cross-sectional view of a portion of the solar module 20 in accordance with the present disclosure. The solar module 20 may include a top layer 110, a top encapsulant layer 120, an array of solar cells 21, a bottom encapsulant layer 140, and a backsheet 150. The cells 21 may be sandwiched between the top layer 110 and the backsheet 150.

The top layer 110 is a transparent layer. By way of non-limiting example, the top layer 110 may be made of a plastic barrier film such as a 3M™ UBF-9L and 510. In another example, the top layer 110 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. The thickness of the top layer 110 may be in the range from about 100 to about 400 microns (μm). Although the top layer is shown as covering only a single solar cell 21, the top layer may cover an array of multiple cells.

The top encapsulant layer 120 may include any of a variety of pottant materials, such as but not limited to poly(ethylene-co-tetrafluoroethylene) (also known as ETFE and sometimes sold under the name Tefzel®), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous PET, urethane acrylic, acrylic, other fluoroelastomers, other materials of similar qualities, or combinations thereof. The thickness of the top encapsulant layer 120 may be in the range of about 400 μm or thinner. Optionally, some embodiments may have more than two encapsulant layers and some may have only one encapsulant layer (either layer 120 or 140).

In many practical implementations it is common for multiple solar cell modules to be electrically connected in series. In such implementations, the first cell and the last cell in the series of electrically coupled cells in a given module may be respectively connected to an upstream module and a downstream module via electrical wires.

The bottom encapsulant layer 140 may be any of a variety of pottant materials, such as but not limited to Tefzel®, polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous PET, urethane acrylic, acrylic, other fluoroelastomers, other materials of similar qualities, or combinations thereof. The thickness of the bottom encapsulant layer 140 may be in the range of about 400 μm or less.

The backsheet 150 provides protective qualities to the underside of the module 20. Materials made of the backsheet 150 may be a multi-layer structure that provides a vapor barrier, an interface for adhesive used for attachment of the module 100 to a structure, such as roof, and provide dielectric protection and cut resistance. By way of non-limiting example, the backsheet 150 may be a plastic film, PET, EPDM, TPO or a multi-layer structure such as 3M™ Scotchshield™ film 15T or 17T, or Coveme dyMat PYE-3000. As seen in FIG. 1, the backsheet structure 150 may be comprised of dielectric layers 152 and 156 and a vapor barrier layer 154, which may be a metal layer sandwiched between the dielectric layers 152 and 156. The dielectric layer 152 or 156 may be made of any electrically insulating materials such as polyethylene terephthalate, or alumina. Dielectric layer 152 is optional. The thickness of the dielectric layer 152 may be in the range from 0 μm to about 150 μm. The thickness of the dielectric layer 156 may be in the range of about 300 μm to about 1.5 millimeters. One of the dielectric layers 152 or 156 may be optionally removed. Optionally, another protective layer may be applied to the dielectric layer for improvement on the voltage withstand, fill pores/cracks, and/or alter the surface properties of the layer that is dip coated, spray coated, or otherwise thinly deposited on the dielectric layer. Optionally, the protective layer may be comprised of a polymer such as but not limited to fluorocarbon coating, perfluoro-octanoic acid based coating, or neutral polar end group, fluoro-oligomer or fluoropolymer. Optionally, the protective layer may be comprised of a silicon based coating such as but not limited to polydimethyl siloxane with carboxylic acid or neutral polar end group, silicone oligomers, or silicone polymers. In one example, the vapor barrier layer 154 may be made of conductive materials, e.g., a metal layer, such as aluminum foil, that may provide vapor barrier for the module 20. The vapor thickness of the vapor barrier layer 154 may be in a range from 25 μm to about 400 μm. The thickness of the backsheet 150 may be in the range about 25 to about 2000 μm.

FIG. 2C shows an example of a photovoltaic cell 21 that may be used in conjunction with aspects of the present disclosure. In the example shown in FIG. 2C, the photovoltaic cell 21 includes a substrate 310, an optional adhesion layer 320, a diffusion barrier layer 321, a back electrode layer 330, a light-absorption layer 350, a buffer layer 360 and a transparent electrode layer 370.

The substrate 310 may be made of metal such as stainless steel or aluminum. Metals such as, but not limited to, copper, steel, coated aluminum, molybdenum, titanium, tin, metallized plastic films, or combinations of the foregoing may also be used as the substrate 310. When a conductive substrate is used, an insulating layer may be formed on the surface of the substrate to keep the surface insulated. Alternative substrates include but are not limited to ceramics, glasses, a polymer such as polyimides (PI), polyamides, polyetheretherketone (PEEK), Polyethersulfone (PES), polyetherimide (PEI), polyethylene naphtalate (PEN), Polyester (PET), related polymers, a metallized plastic, and/or combination of the above and/or similar materials. By way of non-limiting example, related polymers include those with similar structural and/or functional properties and/or material attributes. Any of these substrates may be in the form of foils, sheets, rolls, the like, or combinations thereof. Depending on the conditions of the surface, and material of the substrate, it may be useful to clean and/or smooth the substrate surface.

An optional adhesion layer 320 and diffusion barrier layer 321 may be incorporated between the electrode 330 and the substrate 310. The material of the adhesion layer 320 is selected to promote adhesion of the diffusion barrier layer 321 to the substrate 310 thereby improving adhesion of the electrode 330 to the substrate 310. By way of example, and not by way of limitation, the material of the adhesion layer 320 may be titanium (Ti). The diffusion barrier layer 321 may include a material selected to prevent diffusion of material between the substrate 310 and the electrode 330. The diffusion barrier layer 321 may be a conductive layer or it may be an electrically nonconductive layer. As non-limiting examples, the layer 321 may be composed of any of a variety of materials, including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing. Although not limited to the following, the thickness of this layer can range from 10 nm to 200 nm, more preferably between 50 nm and 200 nm. In some embodiments, the layer may be from 10 nm to 30 nm. Optionally, an interfacial layer may be located above the electrode 330 and be comprised of a material such as including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing.

The back electrode layer 330 may be a metal or semiconductor as long as it is electrically conductive. The thickness of this layer 330 may be in a range of about 0.1 micron to about 25 microns. In one example, molybdenum (Mo) has been widely used as a back electrode layer. The back electrode layer 330 may be deposited on the substrate 310 by DC sputtering or other methods.

Formation of the light-absorption layer 350 may involve multiple steps depending on the type of light absorption layer. By way of example, and not by way of limitation, the light absorption layer may be a so-called I-III-VI₂ layer that includes elements from groups, IB, IIIA, and VIA of the periodic table. In such a case, the first step may involve deposition of a thick precursor layer containing a precursor material, such as Cu and Ga, on the back electrode 330. The thickness of the precursor layer may be in a range from about 0.5 microns to about 2.5 micron. The precursor material may be dispersed in a solvent such as water, alcohol or ethylene glycol with the aid of organic surfactants and/or dispersing agents described herein to form an ink. The precursor layer is annealed with a ramp-rate of 1-5° C./sec, preferably over 5° C./sec, to a temperature of about 225° to about 575° C. preferably for about 30 seconds to about 600 seconds to enhance densification and/or alloying between Cu, In, and Ga in an atmosphere containing hydrogen or nitrogen gas, where the plateau temperature not necessarily is kept constant in time. Some embodiments may heat to a temperature of at least 500° C. Optionally, some embodiments may heat to a temperature of at least 505° C. Optionally, some embodiments may heat to a temperature of at least 510° C. Optionally, some embodiments may heat to a temperature of at least 515° C. Optionally, some embodiments may heat to a temperature of at least 520° C. Optionally, some embodiments may heat to a temperature of at least 525° C. Optionally, some embodiments may heat to a temperature of at least 530° C. Optionally, some embodiments may heat to a temperature of at least 535° C. Optionally, some embodiments may heat to a temperature of at least 540° C. Optionally, some embodiments may heat to a temperature of at least 545° C. Optionally, some embodiments may heat to a temperature of at least 550° C.

Subsequently, this annealed layer may be selenized by heating in the presence of Se vapor in a non-vacuum environment with a ramp-rate of 1-5° C./sec, preferably over 5° C./sec, to a temperature of about 225 to 600° C. for a time period of about 60 seconds to about 10 minutes, where the plateau temperature not necessarily is kept constant in time, to form the thin-film light absorption layer 350 containing one or more chalcogenide compounds containing Cu, In, Ga, and Se. Some embodiments may heat to a temperature of at least 500° C. Optionally, some embodiments may heat to a temperature of at least 505° C. Optionally, some embodiments may heat to a temperature of at least 510° C. Optionally, some embodiments may heat to a temperature of at least 515° C. Optionally, some embodiments may heat to a temperature of at least 520° C. Optionally, some embodiments may heat to a temperature of at least 525° C. Optionally, some embodiments may heat to a temperature of at least 530° C. Optionally, some embodiments may heat to a temperature of at least 535° C. Optionally, some embodiments may heat to a temperature of at least 540° C. Optionally, some embodiments may heat to a temperature of at least 545° C. Optionally, some embodiments may heat to a temperature of at least 550° C.

Optionally, instead of this two-step approach, the layer of precursor material may be selenized without the separate annealing step in an atmosphere containing hydrogen or nitrogen gas, but may be densified and selenized in one step with a ramp-rate of 1-5° C./sec, preferably over 5° C./sec, to a temperature of 225 to 600° C. for a time period of about 120 seconds to about 20 minutes in an atmosphere containing either H₂Se or a mixture of H₂ and Se vapor. Some embodiment use only Se material and completely avoid H₂Se. It should be understood that other embodiments may be configured to include S vapor or H₂S to create the desired copper-indium-gallium-selenium (CIGS) or copper-indium-gallium-selenium-sulfur (CIGSS) absorber. Details of formation of a I-III-VI₂ semiconductor film from particles of precursor materials are described in commonly assigned, co-pending U.S. patent application Ser. No. 13/533,761 filed Jun. 26, 2012 and fully incorporated herein by reference.

The buffer layer 360 is an n-type semiconductor thin film which serves as a junction partner between the compound film and the transparent conducting layer 370. By way of example, buffer layer 160 may include inorganic materials such as cadmium sulfide (CdS), zinc sulfide (ZnS), zinc hydroxide, zinc selenide (ZnSe), n-type organic materials, or some combination of two or more of these or similar materials, or organic materials such as n-type polymers and/or small molecules. Layers of these materials may be deposited, e.g., by chemical bath deposition (CBD) and/or chemical surface deposition (and/or related methods), to a thickness ranging from about 2 nm to about 1000 nm, more preferably from about 5 nm to about 500 nm, and most preferably from about 10 nm to about 300 nm. This may also be configured for use in a continuous roll-to-roll and/or segmented roll-to-roll and/or a batch mode system.

The transparent electrode layer 370 may include a transparent conductive layer 372 and a layer of metal (e.g., Al, Ag, Cu, or Ni) fingers 374 to reduce sheet resistance. The transparent conductive layer 372 may be inorganic, e.g., a transparent conductive oxide (TCO) such as but not limited to indium tin oxide (ITO), fluorinated indium tin oxide, zinc oxide (ZnO) or aluminum doped zinc oxide, or a related material, which can be deposited using any of a variety of means including but not limited to sputtering, evaporation, chemical bath deposition (CBD), electroplating, sol-gel based coating, spray coating, chemical vapor deposition (CVD), physical vapor deposition (PVD), atomic layer deposition (ALD), and the like. Alternatively, the transparent conductive layer 372 may include a transparent conductive polymeric layer, e.g. a transparent layer of doped PEDOT (Poly-3,4-Ethylenedioxythiophene), carbon nanotubes or related structures, or other transparent organic materials, either singly or in combination, which can be deposited using spin, dip, or spray coating, and the like or using any of various vapor deposition techniques. Optionally, it should be understood that intrinsic (non-conductive) i-ZnO or other intrinsic transparent oxide may be used between CdS and Al-doped ZnO. Combinations of inorganic and organic materials can also be used to form a hybrid transparent conductive layer. Thus, the layer 372 may optionally be an organic (polymeric or a mixed polymeric-molecular) or a hybrid (organic-inorganic) material. Examples of such a transparent conductive layer are described e.g., in commonly-assigned US Patent Application Publication Number 20040187317, which is incorporated herein by reference.

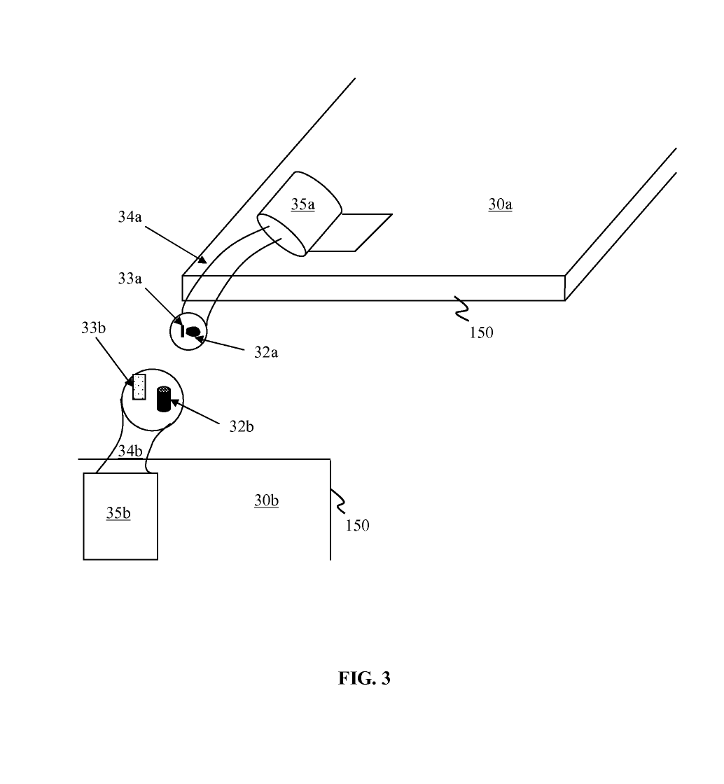

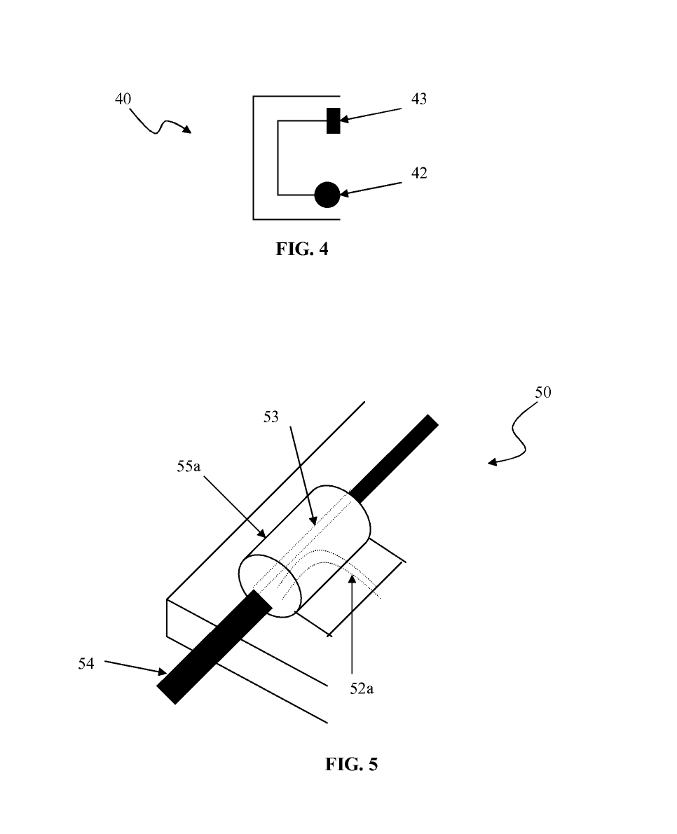

FIG. 3 is a perspective view of an illustrative PV module assembly of the present disclosure where a PV module 30b is connected with a PV module 30a in series. In the module 30b, a bipolar cable 34b from the corner box has two connectors 32b and 33b. The connector 32b is electrically connected to the output of the PV cell string in the module 30b. The connector 33b is electrically connected to a distal end of the bypass cable in the module 30b. In the module 30a, a bipolar cable 34a from the corner box 35a has two recessed connectors 32a and 33a. The connector 32a is electrically connected to the input of the cell string in the module 30a and the connector 33a is coupled to a distal end of the bypass cable in the module 30a. The connector 32b and 33b may be inserted into the connector 32a and 33a respectively, resulting in electrical connection between the PV module 30b and 30a. Connecting multiple PV modules in series as disclosed above may form a PV assembly in accordance with the present disclosure. For the last PV module in the assembly, a bypass device may connect the two connectors of the last bipolar cable together. In particular, FIG. 4 shows an exemplary example of a bypass connector. Specifically, a bypass device 40 includes a terminal connector 42 and a terminal connector 43 which are electrically connected. The connector 42 is coupled to the terminal of the last bipolar cable in the assembly that is connected to the output of the last PV cell string while the connector 43 is coupled to the terminal of the last bipolar cable that is connected to a bypass cable.

In one embodiment, the corner box as described above may be external to the module and integrated with a bipolar cable, a bypass cable and a cable connecting to a cell string. FIG. 5 is an enlarged perspective view depicting portions of an illustrative PV module of the present disclosure. A corner box 55a placed at one corner in the illustrative module 50 has a bipolar cable 54a at one end and two cables 52a and 53 at the other end. The bipolar cable 54a receives an input from an upstream PV module. The cable 52a is electrically connected to the first cell in the series of the PV cells in the PV module 50. The bypass cable 53 is connected to another corner box (not shown) at another corner in the module. The corner box in accordance with this embodiment is a connection device to connect multiple PV modules in series.

While the above is a complete description of the preferred embodiment of the present invention, it is possible to use various alternatives, modifications and equivalents. Any feature described herein, whether preferred or not, may be combined with any other feature described herein, whether preferred or not.

What is claimed is:

1. A photovoltaic module, comprising:
one or more photovoltaic (PV) cells mounted to a support;
a first terminal connected to at least one of the one or more PV cells;
a second terminal connected to at least one of the one or more PV cells; and
a bypass line mounted to the support, wherein the bypass line bypasses the one or more PV cells.

2. The device of claim 1 wherein the one or more PV cells include two or more PV cells connected in series.

3. The device of claim 1, wherein the one or more cells include monocrystalline silicon, polycrystalline silicon, amorphous silicon, cadmium telluride, or copper indium selenide/sulfide.

4. The device of claim 1, wherein the bypass line is laminated and integrated within the photovoltaic module between the support and a top layer.

5. The device of claim 1, wherein the one or more PV cells are laminated and integrated within the PV module between the support layer and a top layer.

6. The device of claim 1, wherein the bypass line and the one or more PV cells are laminated and integrated within the PV module between the support layer and a top layer.

7. The device of claim 1, further comprising at least one structure laminated and integrated within the photovoltaic module between the support and a top layer, the at least one structure configured to provide protection for at least one electrical connections between one of the first and second terminals and at least one of the one or more PV cells.

8. The device of claim 1, further comprising at least one connection device connected to one of the first and second terminals, wherein the at least one connection device comprises a bipolar cable which is split into a bypass cable electrically connected to the bypass line and a cable electrically connected to at least one of the one or more PV cells.

9. The device of claim 1, further comprising at least one connection device connected to one of the first and second terminals, wherein the at least one connection device comprises a housing structure with a bipolar cable at one end, and at the other end, a bypass cable electrically connected to the bypass line and a cable electrically connected to at least one of the one or more PV cells.

10. A photovoltaic (PV) module assembly, comprising:
a first PV module including a first set of one or more PV cells mounted to a first support, a first terminal connected to at least one of the one or more PV cells in the first PV module, a second terminal connected to at least one of the one or more PV cells in the first PV module, and a first bypass line mounted to the first support bypassing the one or more PV cells in the first PV module; and
a second PV module connected in series with the first PV module, the second PV module including a second set of one or more PV cells mounted to a second support, a third terminal connected to at least one of the one or more PV cells in the second PV module, a fourth terminal connected to at least one of the one or more PV cells in the second PV module, and a second bypass line mounted to the second support bypassing the one or more PV cells in the second PV module;
wherein the second terminal of the first PV module is electrically connected to the third terminal of the second PV module, and wherein the first bypass line is electrically connected to the second bypass line.

11. The device of claim 10, wherein the first bypass line is laminated and integrated within the first PV module between the first support and a first top layer, and the second bypass line is laminated and integrated within the second PV module between the second support and a second top layer.

12. The device of claim 10, further comprising at least one structure laminated and integrated within each of the first and second PV modules between the corresponding support and a corresponding top layer, the lat least one structure configured to provide protection for at least one electrical connections between one of the terminals and at least one of the one or more PV cells in the corresponding set.

13. The device of claim 10, further comprising at least one first connection device connected to one of the first and second terminals, wherein the at least one first connection device comprises a first bipolar cable which is split into a first bypass cable electrically connected to the first bypass line and a first cable electrically connected to at least one of the one or more PV cells in the first set; and at least one second connection device connected to one of the third and fourth terminals, wherein the at least one second connection device comprises a second bipolar cable which is split into a second bypass cable electrically connected to the second bypass line and a second cable electrically connected to at least one of the one or more PV cells in the second set.

14. The device of claim 10, further comprising at least one first connection device connected to one of the first and second terminals, wherein the at least one first connection device comprises a first housing structure with a first bipolar cable at one end, and at the other end, a first bypass cable electrically connected to the first bypass line and a first cable electrically connected to at least one of the one or more PV cells in the first set; and at least one second connection device connected to one of the third and fourth terminals, wherein the at least one second connection device comprises a second housing structure with a second bipolar cable at one end, and at the other end, a second bypass cable electrically connected to the second bypass line and a second cable electrically connected to at least one of the one or more PV cells in the second set.

15. The device of claim 10, wherein the fourth terminal of the second PV module is electrically connected to the second bypass line.
